(19) United States
(12) Patent Application Publication
(10) Pub. No.: US 2010/0060561 A1
(43) Pub. Date: Mar. 11, 2010

(54) Shift Register Circuit

(75) Inventor: Steven C. Deane, Redhill (GB)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS, N.V., EINDHOVEN (NL)

(21) Appl. No.: 11/908,968

(22) PCT Filed: Mar. 20, 2006
(86) PCT No.: PCT/IB2006/050855

§ 371 Date: Sep. 18, 2007

(30) Foreign Application Priority Data
Mar. 22, 2005 (EP) 05102311.7

(51) Int. Cl. G09G 3/36; G11C 19/18

(52) U.S. Cl. 345/100; 377/77

(57) ABSTRACT

Each stage of a shift register circuit has an input section (60) and an output section (62). The input section of each stage comprises an input section drive transistor (Tdrive) for coupling a first clocked power line voltage (Pn) to the output of the input section (60), an input section compensation capacitor (Ci) for compensating for the effects of a parasitic capacitance of the input section drive transistor (Tdrive) and a first input section bootstrap capacitor (C2) connected between the gate of the drive transistor and the output of the input section. The input section (60) of each stage uses the output (Rn-i) of the input section (60) of at least one preceding stage as a timing control input for controlling a bootstrap function, and the output section (62) of each stage comprises a circuit which receives the outputs of multiple input sections (60) as timing signals for generating output signals for the output loads (64). This circuit uses one stage to provide the required timing signals, and has feedback of timing signals between stages. This stage has low output load, and can therefore be realized with low size components, and the timing signal retain their shape even when there is degradation of the component characteristics. The other stage drives the load, and the output signals are not used as feedback timing signals, so that the output load does not degrade the timing control signals used in other stages.

This invention relates to shift register circuits, in particular for providing the row voltages to the display pixels of an active matrix display device.

Active matrix display devices comprise an array of pixels arranged in rows and columns, and each comprising at least one thin film drive transistor to and a display element, for example a liquid crystal cell. Each row of pixels shares a row conductor, which connects to the gates of the thin film transistors of the pixels in the row. Each column of pixels shares a column conductor, to which pixel drive signals are provided. The signal on the row conductor determines whether the transistor is turned on or off, and when the transistor is turned on (by a high voltage pulse on the row conductor) a signal from the column conductor is allowed to pass on to an area of liquid crystal material, thereby altering the light transmission characteristics of the material.

The frame (field) period for active matrix display devices requires a row of pixels to be addressed in a short period of time, and this in turn imposes a requirement on the current driving capabilities of the transistor in order to charge or discharge the liquid crystal material to the desired voltage level. In order to meet these current requirements, the gate voltage supplied to the thin film transistor needs to fluctuate with significant voltage swings. In the case of amorphous silicon drive transistors, this voltage swing may be approximately 30 volts.

The requirement for large voltage swings in the row conductors requires the row driver circuitry to be implemented using high voltage components.

There has been much interest in integrating the components of the row driver circuit onto the same substrate as the substrate of the array of display pixels. One possibility is to use polycrystalline silicon for the pixel transistors, as this technology is more readily suitable for the high voltage circuit elements of the row driver circuitry. The cost advantages of producing the display array using amorphous silicon technology are then lost.

There is therefore an interest in providing driver circuits which can be implemented using amorphous silicon technology. The low mobility of amorphous silicon transistors, as well as the stress-induced change in threshold voltage, present serious difficulties in implementing driver circuits using amorphous silicon technology.

The row driver circuit is conventionally implemented as a shift register circuit, which operates to output a row voltage pulse on each row conductor in to turn.

Essentially, each stage of the shift register circuit comprises an output transistor connected between a clocked high power line and the row conductor, and the drive transistor is turned on to couple the row conductor to the clocked high power line to generate a row address pulse. In order to ensure that the voltage on the row conductor reaches the power line voltage (despite the series-connected drive transistor), it is known to take advantage of a bootstrapping effect, using a stray capacitance of the output transistor. This is discussed in U.S. Pat. No. 6,052,426.

A problem with the use of the parasitic capacitances of the drive transistor in this way is that there are other stray effects, and these are also discussed in U.S. Pat. No. 6,052,426. One solution to this is to cancel the effect of the stray capacitance by introducing a first additional capacitor, and to introduce a second additional capacitor dedicated to the bootstrapping operation.

Shift register circuits using additional bootstrapping capacitors in this way are disclosed in U.S. Pat. No. 6,052,426 and in U.S. Pat. No. 6,064,713. In these circuits, the gate of the output transistor is charged by the row pulse of the preceding row, through an input transistor. As a result, the maximum gate voltage which can be applied to the output transistor is dependent on the threshold voltage of the input transistor. Particularly when implementing the shift register circuit using amorphous silicon technology, this can become a limiting factor in the performance of the circuit. This is particularly a problem at low temperatures, as the TFT mobility is then at its lowest, and the threshold voltage is at its highest.

These bootstrapping measures improve the performance of the circuit and improve the tolerance to variations in transistor characteristics. This in turn gives rise to an increased lifespan for the circuit.

Implementations of these circuits use the outputs from previous rows as control signals for a given row, to control the timing of the bootstrapping effects. The finite output impedance of the output transistors, and the capacitive load of the matrix array, causes the output pulses to become to rounded. As these output pulses are used as control inputs for the driver circuits for other rows, this has an effect on the other rows. This provides a limitation to the performance of the gate driver circuit.

According to the invention, there is provided a shift register circuit comprising a plurality of stages, each stage comprising an input section and an output section, each stage being for providing a signal to an output load,

wherein the input section of each stage comprises an input section drive transistor for coupling a first clocked power line voltage to the output of the input section, an input section compensation capacitor for compensating for the effects of a parasitic capacitance of the input section drive transistor and a first input section bootstrap capacitor connected between the gate of the drive transistor and the output of the input section,

wherein the input section of each stage uses the output of the input section of at least one preceding stage as a timing control input for controlling a bootstrap function,

and wherein the output section of each stage comprises a circuit which receives the outputs of multiple input sections as timing signals for generating output signals for the output loads.

This circuit uses two stages to generate a shift register output for driving a load. One stage provides the required timing signals, and has feedback of timing signals from stages to other stages. This stage has low output load, and can therefore be realized with low size components, and the timing signal retain their shape even when there is degradation of the component characteristics. The output stage drives the load, and the output signals are not used as feedback timing signals, so that the output load does not degrade the timing control signals used in other stages. Preferably, the output of each output section is used only for driving the respective output load.

The output section may also comprise:

a first output section input connected to the output of the input section of the preceding stage;

an output section drive transistor for coupling a first clocked power line to voltage to the output of the output section;

an output compensation capacitor for compensating for the effects of a parasitic capacitance of the output section drive transistor;

a first output section bootstrap capacitor connected between the gate of the drive transistor and the output of the stage; and

an output section input transistor for charging the first bootstrap capacitor and controlled by the first output section input.

The input and output sections may thus each have the same design, and differ only in respect of the use of feedback signals.

The input (and output) section of each stage may further comprises a portion coupled to the output of the input section stage two stages before the stage, and wherein the portion comprises a second bootstrap capacitor connected between the gate of the input transistor and the first input.

This circuit arrangement uses two bootstrapping capacitors. One is to ensure the full power supply line voltage can be coupled to the output, and the other is for ensuring that the full row voltage from the preceding stage is coupled through the input transistor to the drive transistor during the gate charging step. The circuit has two precharge cycles of operation—a first cycle when the input transistor gate is precharged, and a second cycle when the drive transistor gate is precharged. This makes the circuit less sensitive to threshold voltage levels or variations, and enables implementation using amorphous silicon technology.

Each stage preferably further comprises a second input connected to the output of the next stage, connected to the gate of a reset transistor which is connected between the gate of the drive transistor and a low power line. The circuit thus has two precharge cycles, one output cycle, and a reset cycle.

The compensation capacitor of each stage is preferably connected between the gate of the drive transistor and a second clocked power line voltage which is clocked complementarily with the first power line voltage. This operates to cancel the effects of parasitic capacitances of the drive transistor.

In one embodiment, the portion (coupled to the output of the input to section stage two stages before the stage) comprises circuit elements for storing a transistor threshold voltage on the second bootstrap capacitor.

For example, the portion may further comprise:

a second input transistor which supplies the output of the stage two stages before the stage to the gate of the first input transistor; and

a decay transistor connected in parallel with the second bootstrap capacitor for decaying the voltage on the second bootstrap capacitor until the threshold voltage of the decay transistor is reached.

The decay transistor preferably has its gate connected to the gate of the first input transistor, so that they are subject to the same voltage stress, and may also have the same dimensions as the first input transistor. The decay transistor is thus used as a model of the input transistor, and the decay transistor threshold voltage is used to represent the input transistor threshold voltage.

The portion may further comprise a reset transistor having its gate connected to the output of the stage, for discharging the second bootstrap capacitor.

In another embodiment, the portion further comprises a second input transistor, which supplies the output of the stage two stages before the stage to the gate of the first input transistor, and this can provide a higher voltage to the second bootstrap capacitor.

The first input transistor may then be connected between an input line and the gate of the drive transistor, and the input line is high when output of the stage before is high, and is high at least immediately after the output of the stage before has a transition from high to low.

The portion may further comprise an input section reset transistor which is connected between the gate of the first input transistor and a low power line.

The shift register circuit of the invention is particularly suitable for use in the row driver circuit of an active matrix display device, for example an active matrix liquid crystal display device.

The invention also provides a method of generating multiple stage shift register circuit outputs for providing a signal to an output load, comprising, for to each stage of the shift register circuit:

controlling an input section to couple a first clocked power line voltage to the output of the input section, compensating for the effects of a parasitic capacitance of a drive transistor, using the output of the stage one stage before the stage to charge the gate of the drive transistor through an input transistor and to charge a first bootstrap capacitor storing the gate-source voltage of the drive transistor; and

controlling an output section using the outputs of the input sections as timing signals for generating output signals to the output loads.

An example of the invention will now be described in detail with reference to the accompanying drawings, in which:

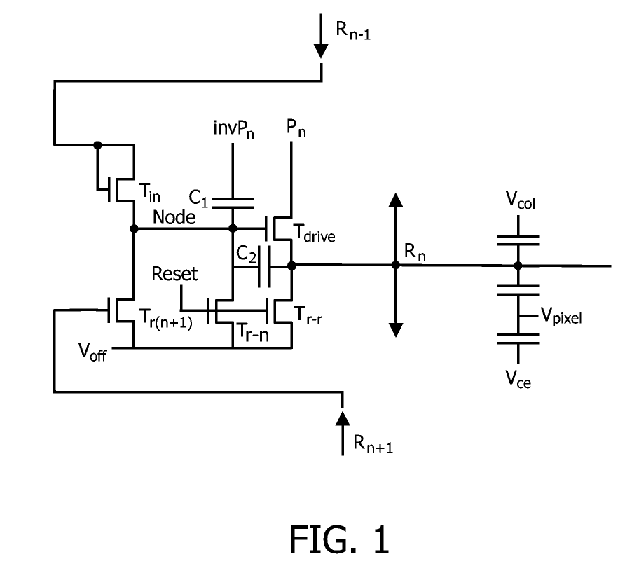

FIG. 1 shows a known shift register circuit;

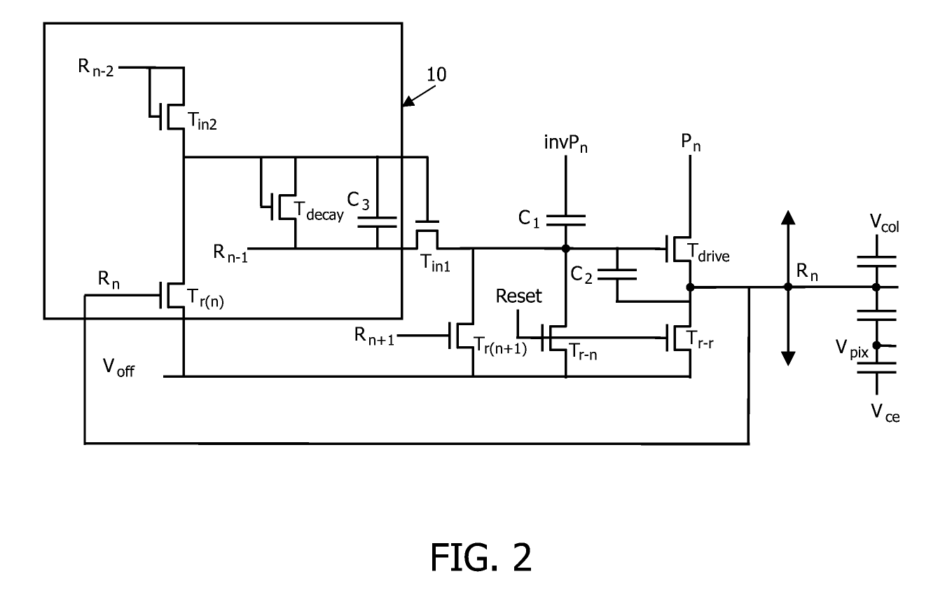

FIG. 2 shows a first example of shift register circuit proposed by the applicant;

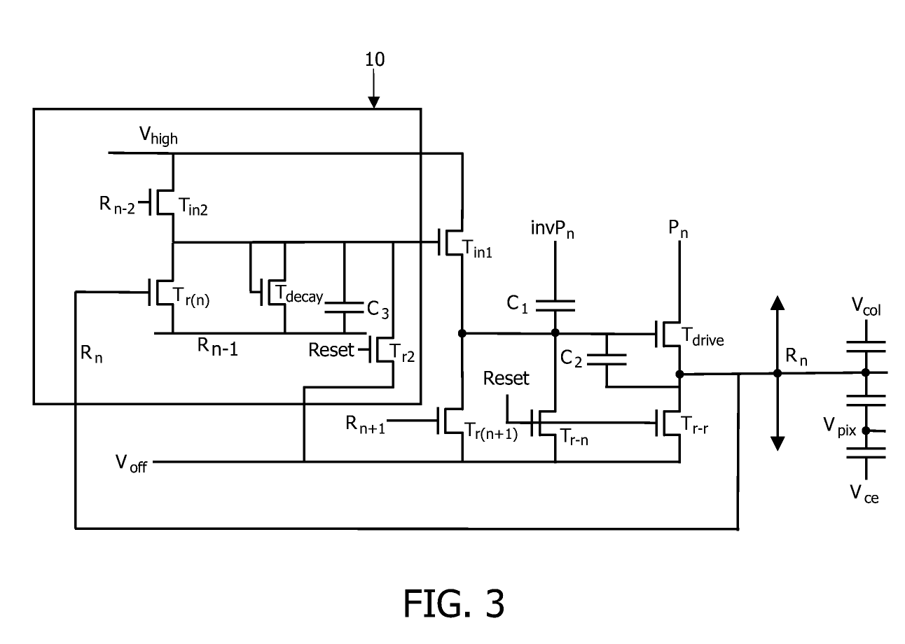

FIG. 3 shows a modification to the circuit of FIG. 2;

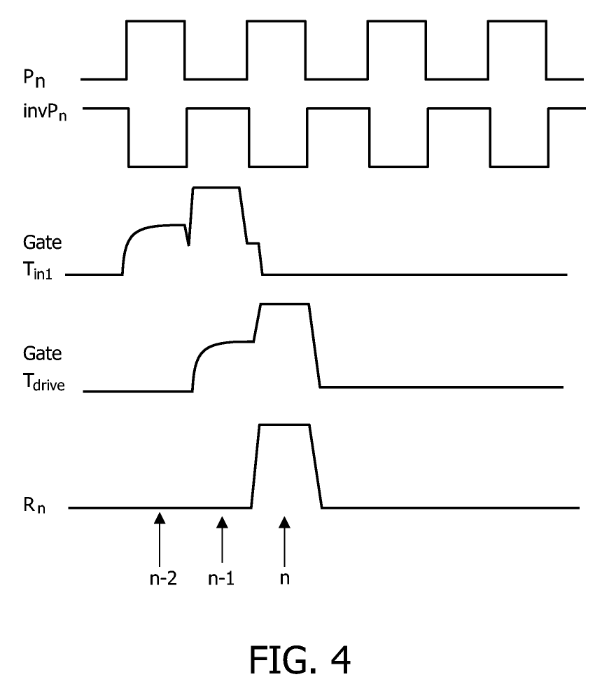

FIG. 4 shows the timing of operation of the circuit of FIG. 2;

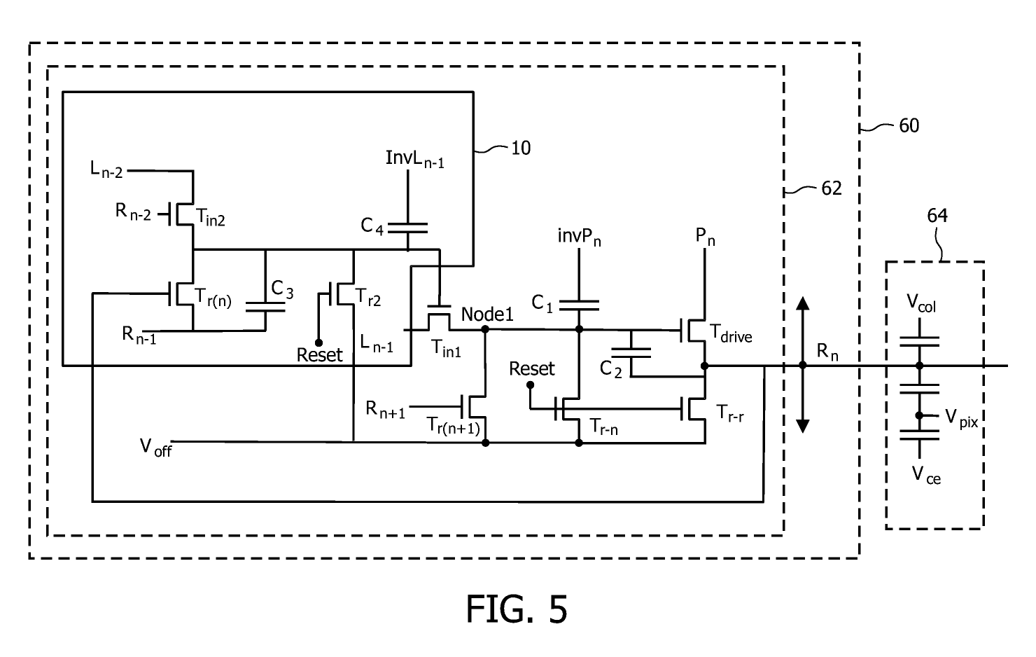

FIG. 5 shows a second example of shift register circuit proposed by the applicant;

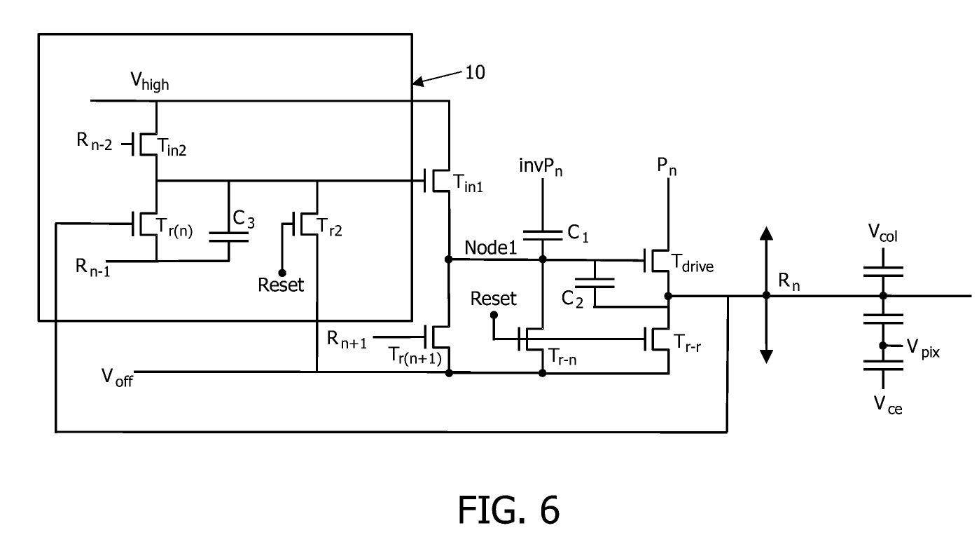

FIG. 6 shows a modification to the circuit of FIG. 5;

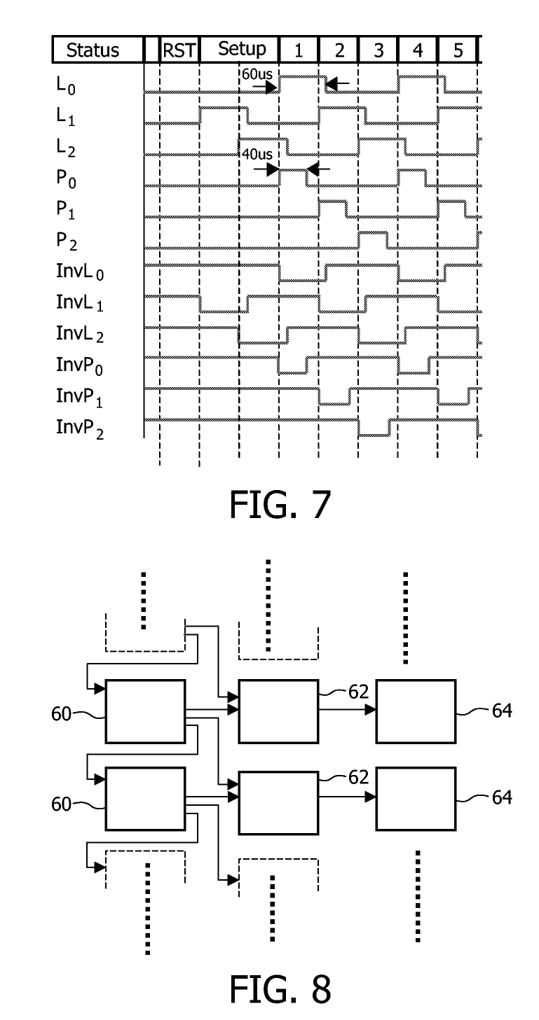

FIG. 7 shows the timing of operation of the circuit of FIG. 5;

FIG. 8 shows a shift register circuit of the invention;

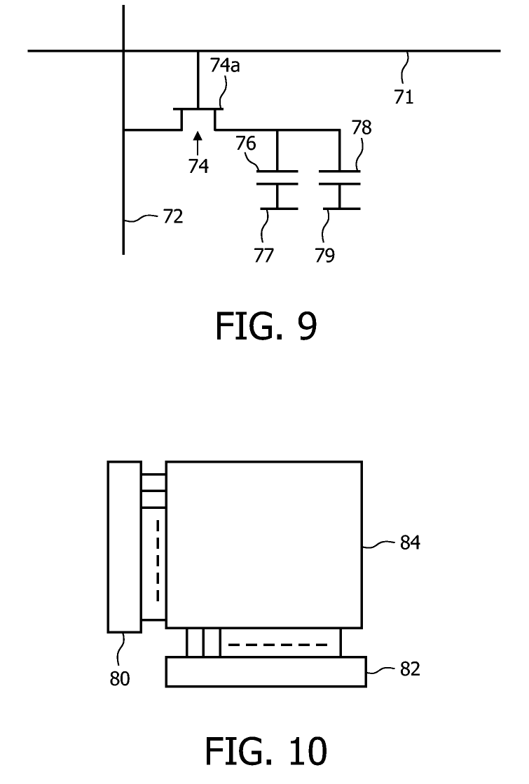

FIG. 9 shows one example of a known pixel configuration for an active matrix liquid crystal display; and

FIG. 10 shows a display device including row and column driver circuitry, in which the circuit of the invention can be used.

FIG. 1 shows a known high impedance gate driver circuit suitable for use in amorphous silicon active matrix liquid crystal displays (AMLCDs). The circuit shown is a single stage of a multiple stage shift register, with each stage being used to supply a row voltage pulse to one row of pixels. A similar circuit to has been described in U.S. Pat. No. 6,052,426.

The circuit comprises an output drive transistor T_{drive} coupled between a clocked power line Pₙ and the row conductor Rₙ which is controlled by the stage. The clocked power line (and the complementary signal invPₙ) is a two phase signal, and the cycles of the clocked power line determine the timing of the sequential operation of the shift register stages.

The row pulse on the previous row Rₙ₋₁ is used to charge the output transistor gate through a diode-connected input transistor Tᵢₙ.

A first capacitor C₁ is connected between the output transistor gate and the control line which carries the complementary signal to the clocked power line Pₙ and the purpose of the capacitor C₁ is to offset the effects of internal parasitic capacitances of the output transistor.

An additional bootstrapping capacitor C₂ is provided between the gate of the output transistor and the row conductor (i.e. the output of the stage).

The stage is also controlled by the row pulse on the next row Rₙ₊₁, which is used to turn off the stage by pulling down the gate voltage of the output transistor. The row pulse on the next row Rₙ₊₁ is provided to the gate of the output transistor through an input transistor Tᵣ₍ₙ₊₁₎ associated with the next row conductor signal.

The circuit also has two reset transistors Tᵣ₋ₙ and Tᵣ₋ᵣ which are used when initially powering the circuit.

In operation, the input transistor Tᵢₙ charges the output transistor gate during the previous row pulse. During this previous row pulse, the power line Pₙ is low and the inverse power line invPₙ is high. The output transistor is turned on by this previous row pulse, but as the power line Pₙ is low, the output of the stage remains low.

During this charging stage, the bootstrapping capacitor C₂ is charged to the row voltage pulse (less the threshold voltage of the input transistor Tᵢₙ).

During the next clock cycle, the clock signal Pₙ is high, and this increase in voltage pulls up the output voltage on the row conductor Rₙ through the output transistor. The effect of the bootstrapping capacitor C₂ is to increase the gate voltage to ensure that the full voltage level of the clocked signal Pₙ is to passed to the row conductor Rₙ. The transistor Tᵣ₍ₙ₊₁₎ subsequently resets the output transistor gate voltage node during the next row pulse.

In the idle state, the coupling of the inverse power line invPₙ through the first additional capacitor C₁ is designed to prevent the output transistor gate from turning on when the output transistor T_{drive} receives a pulse from Pₙ.

The operation of the circuit as described above will be known to those skilled in the art.

As mentioned above, one limitation of the operation of the circuit of FIG. 1 is that the charging of the gate of the output transistor during the timing of the previous row pulse is dependent on the threshold voltage of the input transistor Tᵢₙ. For amorphous silicon transistors, this threshold voltage may be significant, and furthermore may vary significantly with temperature and over time.

The applicant has proposed (but not yet published) an additional input section which is coupled to the output of the stage two stages before the stage. This input section comprises a second bootstrap capacitor connected between the gate of the input transistor and the first input, and operates to cancel the effects of the threshold voltage of the input transistor in the charging of the drive transistor gate.

FIG. 2 shows one stage of a shift register circuit proposed by the applicant.

The circuit includes a precharge circuit 10 which is used to sample a TFT threshold voltage onto a second bootstrap capacitor C₃. This is then used to bootstrap the input TFT Tᵢₙ₁, resulting in good charging of the gate of drive transistor gate voltage regardless of the threshold voltage of the input transistor. The row circuit then resets the charge on C₃, so that the input TFT Tᵢₙ₁ does not drift. The other parts of the circuit of FIG. 2 are the same as in FIG. 1, and a description of these components will not be repeated.

The precharge circuit 10 has an input connected to the output Rₙ₋₂ of the stage two before the stage shown. This output Rₙ₋₂ is coupled through a second input transistor Tᵢₙ₂ to the gate of the first input transistor Tᵢₙ₁.

The second bootstrap capacitor C₃ is connected between the gate of to the first input transistor Tᵢₙ₂ and the output of the preceding stage Rₙ₋₁.

A decay transistor T_{decay} is connected in parallel with the second bootstrap capacitor C₃ and is diode-connected. The gate of the decay transistor is connected to the gate of the first input transistor Tᵢₙ₂ so that they experience the same voltage stress. The decay transistor preferably also has substantially the same dimensions as the first input transistor Tᵢₙ₁.

The precharge section 10 has a reset transistor Tr(n) having its gate connected to the output of the stage Rₙ, for discharging the second bootstrap capacitor C₃.

In operation, the row pulse for the row Rₙ₋₂ two behind the current row is used to charge the gate of the first input transistor Tᵢₙ₂ and the second bootstrap capacitor C₃ via the second input transistor Tᵢₙ₂. This charging is limited by the decay of the charge through the decay transistor T_{decay}.

When row n−2 goes low, the decay transistor T_{decay} causes the voltage across the second bootstrap capacitor C₃ to decay to approximately the TFT threshold voltage. The decay transistor T_{decay} and the first input transistor Tᵢₙ₁ experience the same gate biases at all times, so even in the event of any threshold voltage drift they will exhibit the same threshold voltage.

When row n−1 pulses high, the gate of the first input transistor Tᵢₙ₁ is bootstrapped by the second bootstrap capacitor C₃, resulting in good charging of the gate of the drive transistor T_{drive}.

When row n−1 goes low, the charge is not removed via Tᵢₙ₂ as it is near threshold. Instead, as soon as row n goes high, the discharge transistor Tᵣ₍ₙ₎ discharges the voltage across the second bootstrap capacitor C₃, turning the first input transistor Tᵢₙ₂ completely off.

The circuit operation then proceeds as in the known circuit of FIG. 1.

The reset transistor Tᵣ₍ₙ₎ can be placed with its lower side connected to the low voltage line V_{off} (as shown), or it can be connected to the preceding row n−1.

The circuit of FIG. 2 benefits from a low number of control lines. One disadvantage is that currents required to charge the capacitances in the circuit are drawn from the row outputs from other stages, and this limits performance.

A modification to the circuit of FIG. 2 is shown in FIG. 3, in which the input transistors Tᵢₙ₂ and Tᵢₙ₂ both couple a dc voltage “V_{high}” to the respective capacitor. An additional reset transistor is shown in the input section 10. The coupling of a high dc voltage is more easily achieved with bottom gate transistor technology. This design reduces the load on the previous row, as the charging currents are drawn from the dc supply. This gives improved circuit performance.

A further benefit of the circuit of FIG. 3 is that the circuit can be controlled to provide an idle mode of operation. In an idle state, the circuit presents a high impedance to the row, so that the row pulses can be controlled by a different row driver circuit connected to the other end of the row conductor. It is known to provide two row driver circuits on opposite sides of a display, for example to provide two different modes of operation (different powers, or driving in different directions to allow the display to be used either way up), and an idle mode is required in this case.

The idle mode can be applied to the circuit of FIG. 3 by changing V_{high} to V_{off}, and applying the Pn and inverse pulses.

FIG. 4 is used to explain schematically the timing principles of operation of the circuit of FIG. 2, and the same general principles apply to FIG. 3. The plots show the clocked power supply lines, the gate voltage on the first input transistor Tᵢₙ₁, the gate voltage on the drive transistor T_{drive} and the output Rₙ.

During the timing n−2 of the stage two behind, the second bootstrap capacitor C₃ is precharged. At the end of this phase, there is a drop in voltage until the capacitor stores the threshold voltage. This decay of the voltage on the second bootstrap capacitor continues during the application of the output pulse n−1 to the input transistor, and by the end of the output pulse for row n−1, the voltage across the second bootstrap capacitor will have decayed to the threshold voltage, so that threshold compensation is effective for the input transistor, and the full row voltage is used to charge the first bootstrap capacitor.

During the stage n−1, the output of the stage n−1 is capacitively added to the voltage on the second bootstrap capacitor to derive the gate voltage which drives the first input transistor Tᵢₙ₁.

During stage n−1, the first bootstrap capacitor C₂ is also charged, as can be seen from the plot for the drive transistor gate.

During stage n, the clocked power supply line voltage Pₙ is added to the voltage on the first bootstrap capacitor C₂ to derive the gate voltage of the drive transistor T_{drive}.

The beginning of cycle n is used to discharge the second bootstrap capacitor C₃ through the reset transistor Tᵣ₍ₙ₎ controlled by Rₙ.

The circuit of the invention is particularly suitable for use in the row driver circuit of an active matrix liquid crystal display.

The circuit shown in FIG. 2 uses an extra input stage to correct for the threshold voltage of the input TFT (Tᵢₙ).

The timing diagram of FIG. 4 uses two phase clocking. In practice, the implementation of the circuit of FIG. 3 will use three phase clocking. In other words, the values of Pₙ₋₂ and Pₙ are no longer the same. An example of three phase clocking is shown in FIG. 7, described below. The use of a dc voltage in FIG. 3 requires the three phase control signals to prevent C3 and C2 both charging during the Rₙ₋₂ row pulse.

An alternative approach is to adapt the input stage so that it is not limited to raising the effective gate drive voltage of Tᵢₙ by its threshold voltage, but can raise the drive voltage by a much larger amount. This further improves the charging of the circuit capacitance nodes, and so improves operation.

FIG. 5 shows one stage of another example of shift register circuit proposed by the applicant.

The circuit is the same as the circuit of FIG. 2, apart from the input section 10, and a description of the repeated circuit components will not be given.

The input section 10 again has a second input transistor Tᵢₙ₂ which supplies a signal with timing based on the output of the stage two stages to before the stage to the gate of the first input transistor Tᵢₙ₁. In the circuit of FIG. 4, the output Rₙ₋₂ two stages before controls the timing, but a different voltage waveform is applied to the drain of the second input transistor Tᵢₙ₂, and this is shown as Lₙ₋₂. This will be called a second input line.

Similarly, the first input transistor Tᵢₙ₂ is connected between a first input line Lₙ₋₁ and the gate of the drive transistor T_{drive}. The input line Lₙ₋₁ is high when the output of the stage before is high, so that the operation is similar to FIG. 2. However, for reasons explained below, the input Lₙ₋₁ is also high immediately after the output of the stage before has had a transition from high to low.

The first and second input lines may be clocked signals, but they can be delayed versions of each other, so that there is effectively only one additional clocked signal for each phase of the input clocks Pn. Alternatively, dc voltages may be used.

As in the circuit of FIG. 2, the second bootstrap capacitor C₃ is connected between the output Rₙ₋₁ of the previous stage and the gate of the first input transistor Tᵢₙ₁, and this second bootstrap capacitor is charged with timing based on the output of the stage two stages before. However, there is no decay transistor, so that the charge on the second bootstrap capacitor is not limited to a threshold voltage, but can instead be selected based on the voltage of the input Lₙ₋₂ minus the threshold voltage of Tᵢₙ₂.

An (optional) input section reset transistor Tᵣ₂ is connected between the gate of the first input transistor Tᵢₙ₂ and the low power line V_{off}, and this is for reset of the driver.

The gate of the first input transistor Tᵢₙ₂ may be connected to a clocked signal which is the inverse of the first input line Lₙ₋₁ through a capacitor Ca, and this is to prevent the rising edge of Lₙ₋₁ coupling through the parasitic gate-drain capacitance of Tᵢₙ₂ and turning it on. The capacitor C₄ couples in a complementary signal that cancels this effect out, and the value of C₄ is accordingly chosen to be proportional to the capacitance of Tᵢₙ₂ with the same to proportionality as between C₁ and the drive transistor.

In the embodiment of FIG. 5, the input section feedback reset transistor Rᵣ₍ₙ₎ is connected between the gate of the first input transistor Tᵢₙ₁ and the output of the preceding stage Rₙ₋₁, and again has its gate connected to the output of the stage, for discharging the second bootstrap capacitor C₃.

In operation of the circuit of FIG. 5, the high pulse of the output of the stage two stages behind Rₙ₋₂ again charges the second bootstrap capacitor C₃ through the second input transistor Tᵢₙ₂. The second input line Lₙ₋₂ is high during this time. There is no decay transistor to limit the charging. Thus, instead of charging C₃ to a threshold voltage, it may charge to the voltage of the second input line, less the threshold voltage of the second input transistor. This second input line will typically carry the row voltage, but the timing is not the same, as explained below.

When the preceding stage output Rₙ₋₁ pulses high, and the first input line Lₙ₋₁ is also high, the gate of the first input transistor Tᵢₙ₂ is bootstrapped by the second bootstrap capacitor C₃, resulting in very good charging of the gate of the drive transistor T_{drive}.

When the output Rₙ₋₁ goes low, the charge is not removed from the first bootstrap capacitor C₂ via Tᵢₙ₁ as Lₙ₋₁ is arranged to remain high until after C₃ is discharged. This is the reason why different timing is needed for the first input Lₙ₋₁ than the timing of the output Rₙ₋₁, even though the voltage levels can be the same. As soon as row N goes high, the feedback reset transistor Tᵣ₍ₙ₎ discharges the voltage across C₃, turning Tᵢₙ₁ completely off, in the same way as for the embodiment of FIG. 2.

The circuit operation proceeds in the same way as explained above.

The circuit of FIG. 5 has the same number of TFTs as in FIG. 2, but some extra clock lines are required. However, the bootstrapping of the first input transistor Tᵢₙ₁ is far better.

If the TFT technology has sufficiently good switching characteristics, a DC voltage equivalent to the row high voltage may replace the clocked signals Lₙ.

In this case, the capacitor C₄ and the inverted clocks Lₙ are not required, and circuit performance is improved even further.

The circuit of FIG. 5 has the same further benefits mentioned above that the internal capacitance nodes draw their charging current from the clock lines Ln, rather than the previous rows. This decreases the load which needs to driven by each output TFT.

This circuit also has the benefit that by applying appropriate signals, the row driver may remain in the idle state, while another row driver drives the display with a differing pulse sequence. As mentioned above, this can be used, for example, to provide a display that can scan in forwards or reverse directions.

FIG. 6 shows a modification to the circuit of FIG. 5, in which dc voltages are again used in place of the timing signals Ln, and this is again most appropriate for bottom gate technology. This reduces the clock count and avoids the need for the capacitance C₄. The circuit can be idled in the same way as explained with reference to FIG. 3.

FIG. 7 shows a clock timing diagram for the circuit of FIG. 5, and shows signals for the input lines L for three successive rows as well as signals for the power lines for the three successive rows.

As shown, the pulses on the input lines L have a duration longer than the row address period, and this duration is shown by way of example as 60 μs. The clocked power line pulses are shorter, shown by way of example as 40 μs.

The signals shown in the timing diagram have repeating pulses, so that only three different power P and input line L waveforms and their complements are needed to address the full array.

The circuits described above provide improved tolerance to degradation of transistor characteristics.

One limitation to the performance of the circuits described above results from rounding of the row pulse shapes. These row pulses control the turn-on of the control transistors for other stages of the shift register circuit. The row pulses, which are the output pulses of the stages, become rounded as a result to of the finite output impedance of the output transistors and the capacitive load of the pixel rows driven by the stages. This rounding of pulses reduces the charging of nodes in other stages which use these signals as gate control signals for transistors, limiting the performance of the driver circuit.

This invention relates to a shift register circuit in which a compensation capacitor is used for compensating for the effects of a parasitic capacitance of the drive transistor, and a bootstrap capacitor is used, as in the examples above. The output of at least one preceding stage is used as a timing control input for controlling the bootstrap function. This functionality is provided in an input section. In addition, each stage has an output section which receives the outputs of multiple input sections as timing signals for generating output signals for the output loads.

This arrangement splits the circuit functionality into two portions. An input section is used to derive the different pulse sequences with correct timing, but is not used to drive the output load directly. As a result, the pulse shapes at the outputs are more tolerant to ageing of transistor characteristics, as the transistors are subjected to lower loads. An output stage drives the output load (for example the rows of pixels), but these outputs are not needed as feedback signals, so that any loss in shape in these signals does not affect directly the control signals in other stages of the circuit.

FIG. 8 shows a first example of circuit of the invention.

Each stage of the circuit is arranged as two parts; an input section 60 and an output section 62.

The input section 60 derives the required row pulses in exactly the same manner as described above, with each circuit using feedback from one or more of the other circuits to control the timing. By way of example, the input section may be based on the circuit shown in FIG. 5, and the circuit elements of the input section 60 are outlined in FIG. 5.

The input section 60 uses the outputs as feedback paths, and FIG. 8 shows schematically each input section proving its output to the following circuit. In other words, the circuit providing output Rn uses Rn−1 as an input. The circuit of FIG. 5 uses the two preceding outputs (Rn−1 and Rn−2) as well to as the output of the next stage (Rn+1), but this is not shown in FIG. 8 to reduce complexity of the drawing.

The invention can be applied to any of the circuits described above, including the known circuit of FIG. 1, which uses only the preceding output signal as a timing control signal.

The components used in the output section 62 are also shown outlined in FIG. 5 for the case where the output section is also modeled on the circuit of FIG. 5. The output sections do not provide the feedback paths. Instead the timing control signals are provided as direct connections from the input sections.

The outputs of the output sections each drive a respective load 64, which is also shown outlined in FIG. 5.

The circuit of the invention thus essentially comprises two connected row drivers. The input section row driver provides direct signals to the output section row driver and to the input section row driver as feedback signals, whereas the output section row driver provides only the output signals.

The input section is thus loaded more lightly, and can therefore provide more ideal input signals. The loading on the output section row driver has almost no effect on circuit performance.

This design enables the circuit as a whole to tolerate increased transistor degradation. The circuit can, for example, double the threshold voltage drift which can be tolerated, and this in turn can give rise to an increase in lifetime of a display using the row driver by a factor of approximately 10.

By changing the design parameters, these gains can translated into increased power capability and/or increased frequency of operation. This can then enable amorphous silicon technology to be used for the row driver circuits of large area display panels.

The two copies of the row driver can share the same clock signals, which means that the architecture needs no more input signals than the basic design.

Of course, the circuit area is increased compared to the conventional design, but not by a factor of two, as the clock lines may be shared between the two parts. Furthermore, the two parts of the row driver do not have to be identical in size. All devices in the input section first may be scaled down in size by a factor (for example a factor of 2-10), because the load on the input section is much lower than the array load.

This is particularly the case when the charging of the bootstrap and compensation capacitors is effected from dc voltage lines, rather than using the outputs from other input sections. The input section can then provide near ideal waveforms even when significantly scaled down in device dimensions.

The two row driver sections do not need to be precisely identical in circuit. It is preferable that the two circuits share the same clock signals, so that the overall circuit area is minimised. However, the circuit may combine any two of the circuit examples given above as the input and output sections.

As mentioned above, the use of identical clocking in the two circuit sections is desirable. The use of different clocking for the input and output sections does, however, provide the opportunity to give additional functionality.

In particular, the input section can be clocked as outlined above, to provide the shift register outputs for all rows. This consumes relative low power, as a result of the reduced output load and dimensions for the input section. The output section can then be clocked in a manner to provide a low power partial display function.

An example of the benefit of such a drive scheme is for low power standby modes of portable devices. A mobile telephone in standby mode may need only a limited part of the display area to be used, for the display of the limited information needed when the mobile telephone is turned on but not in use—for example a battery level indicator and signal strength meter.

A further possible benefit of different clocking can be obtained by using shorter duration clock pulses for the output stage than for the input stage. This could be used in a large area display panel, in which the driver is divided into odd lines on one side (for example the left) and even lines on the opposite to side. This allows the input section to run at half the line rate (double the line time) compared to the output section, and can be used to improve performance for large panels.

FIG. 9 shows a conventional pixel configuration for an active matrix liquid crystal display. The display is arranged as an array of pixels in rows and columns. Each row of pixels shares a common row conductor 71, and each column of pixels shares a common column conductor 72. Each pixel comprises a thin film transistor 74 and a liquid crystal cell 76 arranged in series between the column conductor 72 and a common electrode 77. The transistor 14 is switched on and off by the signals provided on the row conductors 71, as described above. Each pixel additionally comprises a storage capacitor 78 which is connected at one end 79 to the next row electrode, to the preceding row electrode, or to a separate capacitor electrode. This capacitor 78 stores a drive voltage so that a signal is maintained across the liquid crystal cell 76 after the transistor 74 has been turned off.

In order to drive the liquid crystal cell 76 to a desired voltage to obtain a required gray level, an appropriate signal is provided on the column conductor 72 in synchronism with the row address pulse on the row conductor 71. This row address pulse turns on the thin film transistor 74, thereby allowing the column conductor 72 to charge the liquid crystal cell 76 to the desired voltage, and also to charge the storage capacitor 78 to the same voltage. At the end of the row address pulse, the transistor 74 is turned off, and the storage capacitor 78 maintains a voltage across the cell 76 when other rows are being addressed. The storage capacitor 78 reduces the effect of liquid crystal leakage and reduces the percentage variation in the pixel capacitance caused by the voltage dependency of the liquid crystal cell capacitance.

The rows are addressed sequentially so that all rows are addressed in one frame period, and refreshed in subsequent frame periods.

As shown in FIG. 10, the row address signals are provided by row driver circuitry 80, and the pixel drive signals are provided by column address circuitry 82, to the array 84 of display pixels. The circuit of the invention is suitable for use in the row driver circuitry, and manufactured using amorphous to silicon technology. The circuit elements can then be integrated onto the active matrix display substrate.

The circuit of the invention results in far better operation at low temperatures and a wider process margin. This can then be used to allow smaller components to be used for a given application, resulting in lower power and a smaller circuit design, despite the extra TFTs involved (which are all small).

In the example above, the reset transistor Tᵣ₍ₙ₊₁₎ controlled by the next stage is connected between the gate of the drive transistor and the low power line. It may instead be connected between the gate of the drive transistor and the row output, namely across the first bootstrap capacitor C₂. Furthermore, this reset transistor could be connected to the output of a different output stage, for example stage n+2, n+3 etc (up to n+number of clock phases−1).

As will be apparent from the examples above, the reset transistor Rᵣ₍ₙ₎ of the input section can be connected between the gate of the first input transistor Tᵢₙ₁ and the low power line V_{off} or between the gate of the first input transistor Tᵢₙ₁ and the preceding row output n−1, namely across the second bootstrap capacitor C₃. These two possibilities are possible for both examples shown. The gate of this reset transistor could also be connected to the output of a different output stage, for example stage n+1, n+2 etc. The circuits can also function without the reset transistor at all.

In the example of FIG. 5, the second input transistor Tᵢₙ₂ can be diode-connected as in the example of FIG. 2, thereby removing the connection to Lₙ₋₂. Thus, the embodiment of FIG. 5 does not need connection to the second input line Lₙ₋₂. The connection to Lₙ₋₂ provides the ability of the circuit to remain in an idle state, while the display is driven differently, as mentioned above.

The detailed examples above use the output from two stages behind as a control signal. However, the preferred double-precharge effect this produces can be achieved using an output from a stage further back. For example, instead of using Rn−1 and Rn−2 as in the examples above, the circuit may be designed to use Rn−2 and Rn−4. This may be desirable if the gate driver is to split into odd and even halves, each on different sides of the array. This example also shows that the gate charging controlled by the output of the preceding stage in the examples shown, can in fact also be controlled by a stage further back.

As mentioned above, the invention is particularly suitable for implementation using amorphous silicon transistors, and for this reason, the circuits shown use n-type transistors. However, the invention is also applicable to other circuit technologies, for example organic thin film transistors (which are frequently implemented as p-type devices) or low temperature polysilicon (which may be implemented as PMOS devices). The circuits of the invention can implemented using p-type transistors without modification to the operating principles, and this will be well understood by those skilled in the art. The invention is not intended to be limited to any particular technology type.

It will therefore be apparent that there are numerous variations to the specific circuit described in detail, and many other modifications will be apparent to those skilled in the art.

1. A shift register circuit comprising a plurality of stages, each stage comprising an input section (60) and an output section (62), each stage being for providing a signal to an output load (64),
wherein the input section of each stage comprises an input section drive transistor (T_{drive}) for coupling a first clocked power line voltage (Pn) to the output of the input section (60), an input section compensation capacitor (C₁) for compensating for the effects of a parasitic capacitance of the input section drive transistor (T_{drive}) and a first input section bootstrap capacitor (C₂) connected between the gate of the drive transistor and the output of the input section,
wherein the input section (60) of each stage uses the output (Rₙ₋₁) of the input section (60) of at least one preceding stage as a timing control input for controlling a bootstrap function,
and wherein the output section (62) of each stage comprises a circuit which receives the outputs of multiple input sections (60) as timing signals for generating output signals for the output loads (64).

2. A circuit as claimed in claim 1, wherein the input section (60) of each stage further comprises:
a first input section input (Rₙ₋₁) connected to the output of the input section of a preceding stage; and
an input section input transistor (Tᵢₙ₁) for charging the first bootstrap capacitor (C₂) and controlled by the first input (Rₙ₋₁).

3. A circuit as claimed in claim 1, wherein the output of each output section (62) is used only for driving a respective output load

4. A circuit as claimed in claim 1, wherein the output section (62) comprises:
a first output section input (Rₙ₋₁) connected to the output of the input section of the preceding stage;
an output section drive transistor (T_{drive}) for coupling a first clocked power line voltage (Pn) to the output of the output section;
an output compensation capacitor (C₁) for compensating for the effects of a parasitic capacitance of the output section drive transistor (T_{drive});
a first output section bootstrap capacitor (C₂) connected between the gate of the drive transistor and the output of the stage; and
an output section input transistor (Tᵢₙ₁) for charging the first bootstrap capacitor and controlled by the first output section input.

5. A circuit as claimed in claim 1, wherein the input section (60) of each stage further comprises a portion (10) coupled to the output (Rₙ₋₂) of the input section stage two or more stages before the stage, and wherein the portion (10) comprises a second input section bootstrap capacitor (C₃) connected between the gate of the input section input transistor (Tᵢₙ₁) and the first input section input (Rₙ₋₁).

6. A circuit as claimed in claim 1, wherein the output section of each stage further comprises a portion (10) coupled to the output of (Rₙ₋₂) the input section stage two or more stages before the stage, and wherein the portion (10) comprises a second output section bootstrap capacitor (C₃) connected between the gate of the output section input transistor (Tᵢₙ₁) and the first output section input.

7. A circuit as claimed in claim 1, wherein the input section (60) of each stage further comprises a second input section input (Rₙ₊₁) connected to the output of the input section of the next stage.

8. A circuit as claimed in claim 7, wherein the second input section input (Rₙ₊₁) is connected to the gate of a reset transistor (Rᵣ₍ₙ₊₁₎) which is connected between the gate of the input section drive transistor and a low power line.

9. A circuit as claimed in claim 1, wherein the input section compensation capacitor (C₁) of each stage is connected between the gate of the input section drive transistor and a second clocked power line voltage (invPn) which is clocked complementarily with the first power line voltage (Pn).

10. A circuit as claimed in claim 5, wherein the portion (10) comprises circuit elements for storing a transistor threshold voltage on the second input section bootstrap capacitor (C₃).

11. A circuit as claimed in claim 5, wherein the portion (10) further comprises:
a second input section input transistor (Tᵢₙ₂) which supplies the output of the stage two or more stages before the stage to the gate of the first input section input transistor (Tᵢₙ₁); and
a decay transistor (T_{decay}) connected in parallel with the second input section bootstrap capacitor (C₃) for decaying the voltage on the second input section bootstrap capacitor until the threshold voltage of the input section decay transistor is reached.

12. A circuit as claimed in claim 11, wherein the input section decay transistor has substantially the same dimensions as the first input section input transistor.

13. A circuit as claimed in claim 5, wherein the portion (10) further comprises a second input section input transistor (Tᵢₙ₂) which supplies the output of the stage two or more stages before the stage to the gate of the first input section input transistor (Tᵢₙ₁).

14. A circuit as claimed in claim 13, wherein the first input section input transistor (Tᵢₙ₁) is connected between an input line (Lₙ₋₁) and the gate of the input section drive transistor, and wherein the input line is high when output of the stage before is high, and is high at least immediately after the output of the input section of the stage before has a transition from high to low.

15. A circuit as claimed in claim 14, wherein the input line (V_{high}) is permanently high during operation of the circuit.

16. A circuit as claimed in claim 14 wherein the portion (10) further comprises a reset transistor (Tᵣ₍ₙ₋₁₎) which is connected between the gate of the first input section input transistor and a low power line.

17. A circuit as claimed in claim 5, wherein the portion (10) further comprises a feedback reset transistor (Tᵣ₍ₙ₎) having its gate connected to the output of the input section stage, for discharging the second input section bootstrap capacitor (C₃).

18. A circuit as claimed in claim 1, wherein the input section and the output section of each stage have the same circuit elements, and wherein:
in the input section (60), the input section inputs derived from other input section outputs are provided as feedback paths, and wherein
in the output section (62), the output section inputs derived from other input section outputs are provided as direct paths between the input and output sections.

19. A circuit as claimed in claim 1, wherein the input section and the output section share common clock signals (Pn, invPn).

20. A circuit as claimed in claim 1, wherein the input section and the output section have different clock signals, the clock signals of the output section being used to implement a partial output scheme.

21. A circuit as claimed in claim 1, implemented using amorphous silicon technology.

22. An active matrix display device, comprising:
an array (84) of active matrix display pixels;
row driver circuitry (80) comprising a shift register circuit as claimed in claim 1.

23. (canceled)

24. A method of generating multiple stage shift register circuit outputs for providing a signal to an output load (64), comprising, for each stage of the shift register circuit:
controlling an input section (60) to couple a first clocked power line voltage (Pn) to the output of the input section (60), compensating for the effects of a parasitic capacitance of a drive transistor (T_{crive}), using the output (Rₙ₋₁) of the stage one or more stage before the stage to charge the gate of the drive transistor through an input transistor (Tᵢₙ₁) and to charge a first bootstrap capacitor (C₂) storing the gate-source voltage of the drive transistor; and
controlling an output section (62) using the outputs of the input sections as timing signals for generating output signals to the output loads.

25. A method as claimed in claim 24, wherein controlling the input section (60) comprises using the output (Rₙ₋₂) of the stage two ore more stages before the stage to charge the gate of an input transistor (Tᵢₙ₁), and storing the gate-source voltage on a second bootstrap capacitor (C₃); and
coupling a first clocked power supply line voltage (Pn) to the output of the stage through the drive transistor.

26. A method as claimed in claim 24, wherein controlling the output section comprises coupling a second clocked power line voltage to the output of the output section, compensating for the effects of a parasitic capacitance of a drive transistor, using the output of the stage one or more stage before the stage to charge the gate of the drive transistor through an input transistor and to charge a first bootstrap capacitor storing the gate-source voltage of the drive transistor.
